(19) United States
(12) Patent Application Publication
(10) Pub. No.: US 2026/0239556 A1
(43) Pub. Date: Aug. 13, 2026

(54) CABINET TO FACILITATE NOISE REDUCTION

(71) Applicant: VERTIV CORPORATION, Westerville, OH (US)

(72) Inventor: Adarsh KHANDELWAL, Pune (IN)

(73) Assignee: VERTIV CORPORATION, Westerville, OH (US)

(21) Appl. No.: 19/537,832

(22) Filed: Feb. 12, 2026

(30) Foreign Application Priority Data
Feb. 12, 2025 (IN) 202511011894

(51) Int. Cl. H05K 7/20; B32B 27/32; E04B 1/86

(52) U.S. Cl. CPC H05K 7/20145; B32B 27/325; E04B 1/86; H05K 7/20745

(57) ABSTRACT

Present disclosure provides a cabinet for housing electronic components and a method of manufacturing a wall panel associated with the cabinet. The cabinet includes a plurality of walls defining an enclosure. A wall of the cabinet includes a first sheet and a second sheet substantially coextensive with and spaced-apart from the first sheet to form an interlayer region. The interlayer region contains an interlayer medium configured to inhibit transmission of sound from the interior of the enclosure to the exterior. The interlayer medium may be a vacuum cavity or a compressed sound-absorbing material. The multilayer wall construction preserves mechanical robustness while enabling significant noise reduction without necessitating changes to internal component layout. The cabinet is suitable for electronic equipment that generates operational noise, such as fan-cooled systems, and can be implemented in full or selectively on one or more walls to meet acoustic performance targets.

### CROSS-REFERENCE TO RELATED APPLICATION

This patent application claims priority to Indian Patent Application No. IN 202511011894, filed on Feb. 12, 2025, entitled “A CABINET TO FACILITATE NOISE REDUCTION,” and assigned to the assignee hereof. The entire disclosure of the above application is incorporated herein by reference.

### FIELD

Embodiments of the present disclosure generally relate to acoustic noise control for electronic equipment enclosures, specifically to the design of active or passive cabinets with multilayer walls that inhibit sound transmission from internal fans or similar devices while maintaining thermal performance.

### BACKGROUND

This section provides background information related to the present disclosure which is not necessarily prior art.

In many industrial, commercial, and residential environments, electronic equipment enclosures or cabinets are used to house sensitive electrical and electronic components. These cabinets are essential for both protection and thermal management. As shown in FIG. 6 (Prior Art), a typical sealed cabinet 600 incorporates solid walls and is intended to isolate the internal components from external contaminants and environmental factors. These components often generate significant heat during operation, necessitating the use of cooling mechanisms, such as fans or ventilation systems within the cabinet to maintain optimal operating temperatures. The presence of such cooling mechanisms, while essential for thermal management, frequently results in generation of unwanted noise. The unwanted noise can be disruptive and may significantly affect the working environment, particularly in noise-sensitive settings, such as offices, data centers, hospitals, and residential areas.

Conventional methods employed to mitigate noise in such cabinets include the use of acoustic insulation materials, sound-damping linings, or modifications of fan speeds. In some design approaches, as depicted in FIG. 7 (Prior Art), cabinet assemblies 700 consist of isolated panels or sections (e.g., labeled as 702) constructed using conventional joining and sealing techniques. These solutions frequently rely on component isolation and basic structural designs, which can offer limited effectiveness against airborne and structure-borne noise. The presence of air gaps, rigid connections, and the overall pathway for sound through the panel materials limit the achievable attenuation.

Acoustic insulation often involves the addition of foam or other sound-absorbing materials inside the cabinet walls. While this approach can reduce noise levels to some extent, it comes with drawbacks such as added material costs, increased cabinet weight, and potential reduction in the effective volume for equipment installation. Additionally, insulation materials may degrade over time or be susceptible to environmental factors like moisture and dust, which can limit their effectiveness and lifespan.

Controlling fan speeds is another common approach to noise reduction. Lowering the fan speed reduces noise emissions but often compromises cooling efficiency. Insufficient cooling can result in overheating or reduction in the lifespan and reliability of the housed electronic components, leading to increased maintenance costs and potential equipment downtime, which may be critical concerns for many users. In some cases, external sound barriers or enclosures are employed around noisy cabinets or machinery, but such solutions are bulky, costly, and may complicate maintenance access and airflow.

Furthermore, with the increasing density and complexity of electronic systems, especially in data centers, telecommunications, and industrial control applications, the issue of noise pollution has become more critical. Regulatory requirements and workplace standards increasingly mandate noise reductions to ensure safe and comfortable working conditions.

Thus, there is a general need for improved cabinet construction techniques that inherently reduce noise generation and transmission without compromising thermal management or increasing complexity and cost significantly.

### SUMMARY

This section provides a general summary of the disclosure, and is not a comprehensive disclosure of its full scope or all of its features.

Solution to one or more drawbacks of existing technology, and additional advantages are provided through the present subject matter, including effective noise reduction from internal cooling fans or rotating machinery without compromising thermal performance of housed electronic components. Additional features and advantages are realized through integral structural construction of cabinet walls using standard materials and fastening techniques for cost-effectiveness, durability, simple manufacturability, ease of interior access for maintenance, and versatility across active/passive, indoor/outdoor, sealed/open-site enclosures. Other embodiments and aspects interrupt sound wave transmission by damping propagation media within walls, balancing noise control, cooling efficiency, manufacturability, and reliability to overcome prior art limitations.

In an embodiment, the present disclosure relates to a cabinet for housing electronic components. The cabinet includes a plurality of walls defining an enclosure. At least one wall of the plurality of walls includes a first sheet and a second sheet spaced apart to form an interlayer region. The wall further includes an interlayer medium provided in the interlayer region. The interlayer medium inhibits transmission of sound from an interior of the enclosure to an exterior. The interlayer medium includes one of a vacuum cavity or a compressed sound-absorbing material.

In an aspect of the present disclosure, the cabinet includes a plurality of fasteners coupling the first sheet and the second sheet. In some embodiments, the plurality of fasteners may be configured to maintain compression of the sound-absorbing material to eliminate air gaps therein.

In an aspect of the present disclosure, the plurality of fasteners comprises at least one of bolts, rivets, welding, or adhesives.

In an aspect of the present disclosure, the plurality of fasteners compresses the sound-absorbing material to at least 80% of its uncompressed thickness.

In an aspect of the present disclosure, the compressed sound-absorbing material is selected from the group comprising acoustic foam, fiberglass, mineral wool, and polymeric sound-damping composites.

In an aspect of the present disclosure, vacuum in the vacuum cavity is maintained in the interlayer medium using a vacuum pump.

In an aspect of the present disclosure, the vacuum has a pressure less than 100 Pa.

In an aspect of the present disclosure, the first sheet and the second sheet are made of metal.

In an aspect of the present disclosure, the cabinet is one of an active cabinet or a passive cabinet.

In an aspect of the present disclosure, the at least one wall having the interlayer medium is a side wall, a top wall, or a door of the cabinet.

In an aspect of the present disclosure, the cabinet is an Outdoor Site Premises (OSP) enclosure.

In an aspect of the present disclosure, the vacuum cavity forms a vacuum shroud that blocks propagation of sound waves.

In another embodiment, the present disclosure relates to a method of manufacturing a wall panel associated with a cabinet for housing electronic components. The method includes the step of providing a first sheet and a second sheet. The method further includes the step of aligning the first sheet and the second sheet with an interlayer region defined therebetween. The method further includes the step of securing the first sheet to the second sheet using a plurality of fasteners to either seal the interlayer region to define a vacuum cavity or compress a sound-absorbing material positioned between the first sheet and the second sheet to eliminate air gaps.

In an aspect of the present disclosure, the method further includes evacuating air from the interlayer region to create a vacuum within the vacuum cavity.

In an aspect of the present disclosure, the vacuum is created using a vacuum pump.

In an aspect of the present disclosure, the sound-absorbing material is compressed by applying a torque of at least 5 Nm to each fastener of the plurality of fasteners.

In an aspect of the present disclosure, the plurality of fasteners includes at least one of bolts, rivets, welding, or adhesives.

In an aspect of the present disclosure, the compressed sound-absorbing material is selected from the group consisting of acoustic foam, fiberglass, mineral wool, and polymeric sound-damping composites.

In an aspect of the present disclosure, the vacuum cavity forms a vacuum shroud that blocks propagation of sound waves.

In an aspect of the present disclosure, the first sheet and the second sheet are made of metal.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way. In the drawings:

FIG. 1 illustrates a perspective view of a proposed cabinet, in accordance with an aspect of the present disclosure;

FIG. 2 illustrates an isometric view of the proposed cabinet, in accordance with an aspect of the present disclosure;

FIG. 3A illustrates a structure of a segment of the interlayer region, in accordance with an aspect of the present disclosure;

FIG. 3B illustrates a sectional view, partially cut-away perspective of the segment of the interlayer region, highlighting the multilayer configuration of the interlayer region, in accordance with an aspect of the present disclosure;

FIG. 3C illustrates a sectional view, partially cut-away perspective of the segment of the interlayer region, highlighting the material located within the interlayer region, in accordance with an aspect of the present disclosure;

FIG. 4 illustrates a cross-sectional view of the proposed cabinet, in accordance with an aspect of the present disclosure;

FIG. 5 illustrates a flowchart outlining a method of constructing the proposed cabinet to facilitate noise reduction, in accordance with an aspect of the present disclosure;

FIG. 6 illustrates the cabinet having conventional structural components for noise reduction, in accordance with prior art; and

FIG. 7 illustrates the cabinet having conventional structural components for noise reduction, in accordance with prior art.

While the disclosed cabinet is susceptible to various modifications and alternative forms, specific embodiments thereof have been shown by way of example in the drawings and are described herein in detail. The figures and written description are not intended to limit the scope of the inventive concepts in any manner. Rather, the figures and written description are provided to illustrate the inventive concepts to a person of ordinary skill in the art by reference to particular embodiments.

### DETAILED DESCRIPTION

For the purpose of promoting an understanding of the principles of the disclosure, reference will now be made to the embodiment illustrated in the figures and specific language will be used to describe them. It will nevertheless be understood that no limitation of the scope of the disclosure is therefore intended. Such alterations and further modifications in the illustrated system, and such further applications of the principles of the disclosure as would normally occur to those skilled in the art are to be construed as being within the scope of the present disclosure. It will be understood by those skilled in the art that the foregoing general description and the following detailed description are exemplary and explanatory of the disclosure and are not intended to be restrictive thereof.

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

Unless otherwise defined, all technical and scientific terms used herein have the same meaning as commonly understood by those skilled in the art to which this disclosure belongs. The system, methods, and examples provided herein are only illustrative and not intended to be limiting.

Embodiments of the present disclosure provide a cabinet structure designed for housing electronic or electrical components with enhanced noise reduction capabilities. More specifically, it pertains to a cabinet comprising specially engineered multilayer walls that inhibit the transmission of sound generated inside the enclosure, such as noise from cooling fans, without compromising the cabinet's thermal performance. The multilayered wall cabinet incorporates either a compressed sound-absorbing interlayer or a vacuum cavity between two sheets. The cabinet is applicable across a range of installation environments and enclosure types, addressing noise control challenges inherent in modern electronic equipment housing while maintaining ease of manufacture, durability, and effective equipment protection.

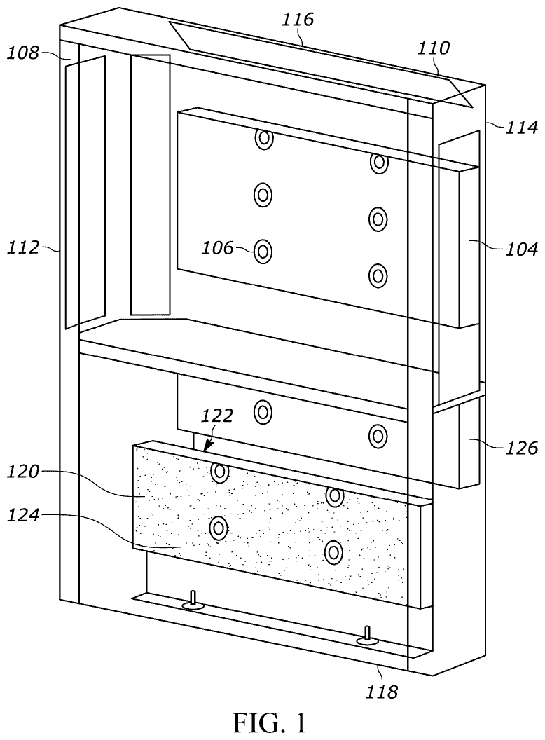

Referring now to the drawings, and more particularly to FIG. 1 through FIG. 5, where similar reference characters denote corresponding features consistently throughout the figures, there are shown preferred embodiments, and these embodiments are described in the context of the following exemplary system and/or method.

FIG. 1 illustrates a perspective view of a proposed cabinet 100 to facilitate noise reduction, in accordance with an aspect of the present disclosure. The cabinet 100 may be designed for housing electronic or electrical components with integrated noise reduction capability. Specifically, the disclosure provides a novel wall construction for the cabinet 100 that inhibits the transmission of sound generated within the enclosure, such as noise from cooling fans.

The cabinet 100 includes multiple walls comprising a front wall 108, a back wall 110, left wall 112, a right wall 114, a roof 116 and a base 118 that collectively define an enclosure for housing electronic or electrical components. At least one wall of the multiple walls includes a multilayer structure with a first sheet 120 and a second sheet 122 spaced apart to form an interlayer region 104. The interlayer region 104 contains an interlayer medium 124 configured to inhibit the propagation of sound waves from inside the cabinet 100 to the outside environment.

In one embodiment, the interlayer medium 124 may include a compressed acoustic material. For example, the space 104 between the two sheets 120 and 122 can be filled with a sound-absorbing material, such as acoustic foam, fiberglass, mineral wool, or a polymeric sound-damping composite. The sheets 120 and 122 may be mechanically joined and compressed using fasteners 106, such as bolts, rivets, welding, or adhesives. The mechanical joining and compression preferably eliminates air gaps to maximize sound attenuation. In one embodiment, the sound-absorbing material is compressed to at least 80% of its original thickness to enhance its acoustic performance.

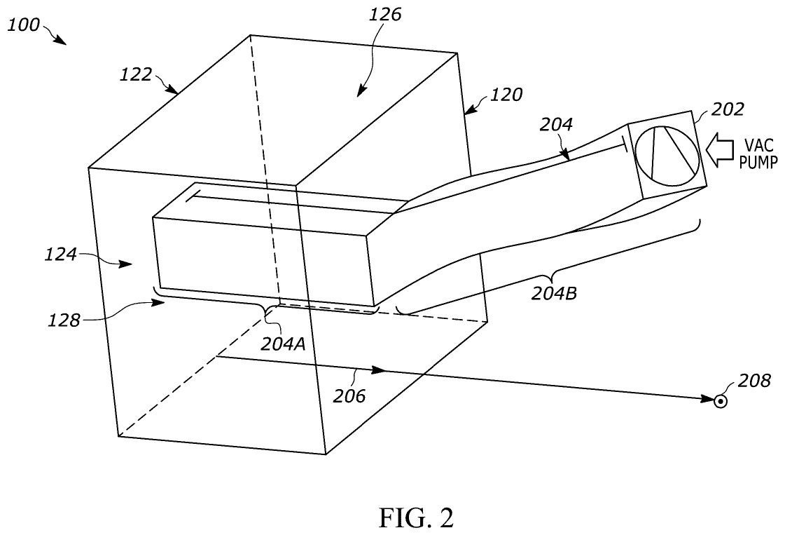

In an alternate embodiment, the interlayer medium 124 may be a vacuum cavity 126. The space between the first sheet 120 and the second sheet 122 can be evacuated using a vacuum pump 202, shown in FIG. 2, to form the vacuum cavity 206. By removing the air, the medium for sound transmission is eliminated, substantially reducing the passage of noise through the wall. The vacuum cavity 126 can be maintained at pressures less than 100 Pa for optimal performance. The vacuum cavity thus acts as an acoustic barrier or “vacuum shroud” within the cabinet wall.

In one embodiment, the first sheet 120 and the second sheet 122 are preferably made of metal for structural strength and durability. The fasteners 106 are used to couple the first sheet 120 and the second sheet 122, either to compress the sound-absorbing material or to seal the interlayer region 104 and maintain the vacuum. The fastening technique, including torque application sufficient to eliminate air gaps (e.g., at least 5 Nm per bolt), ensures reliable insulation and the elimination of air gaps or leaks. The wall construction may be applied to various sides of the cabinet 100, such as the front wall 108, the back wall 110, the left wall 112, the right wall 114, the roof 116 and the base 118 etc. The selective wall construction offers flexibility making the disclosure suitable for multiple cabinet configurations.

The disclosed method of manufacturing a noise damping wall panel associated with a cabinet for housing electronic components can be implemented in both active (fan-cooled) and passive cabinets. Similarly disclosed method is applicable to indoor, outdoor, sealed, and open-site enclosures. The disclosed method does not compromise thermal performance of the electronic components housed within the wall panel, since the cooling features facilitate free airflow around the electronic components encased within the noise-damping wall panel. The sound-insulating wall panel design is created using standard manufacturing techniques and materials, supporting commercial feasibility and cost-effectiveness.

Other embodiments may involve varying interlayer materials, fastening schemes, or the inclusion of additional features (such as dust protection or enhanced cooling modules). The inventive concept encompasses a wide range of modifications and equivalents, maintaining the principle of noise reduction via advanced wall construction and interlayer engineering.

FIG. 2 illustrates an isometric view of proposed cabinet 100 to facilitate noise reduction, in accordance with an aspect of the present disclosure. To maintain vacuum inside the vacuum cavity 126 located between the first sheet 120 and the second sheet 122, the cabinet 100 may be coupled to a vacuum pump 202, via a channel 204 as illustrated in FIG. 2. A first part 204A of a conduit 204 runs from the inner portion 128 of the vacuum cavity 126 to the first sheet 120. A second part 204B of the conduit 204 runs from the first sheet 120 to the vacuum pump 202. Air from the vacuum cavity 126 is removed by the vacuum pump 202. The direction of air flow is shown by an airflow direction arrow 206, generally indicating the evacuation path for the air from the inner portion 128 of the vacuum cavity 126 to the area 208 outside the cabinet 100. The effect of the operation of the vacuum pump 202 is to maintain a low-pressure or near-vacuum state within the vacuum cavity 206 or the material located in the interlayer region 104, to enhance sound attenuation.. All parts of the cabinet 100, including the noise-attenuating walls, are accessible for maintenance and do not interfere with the cooling or protection of components housed within the cabinet 100.

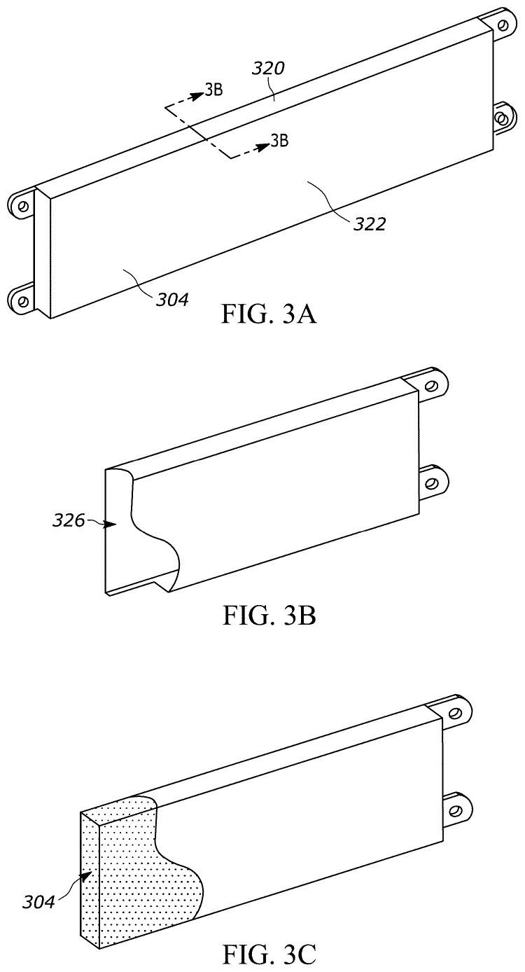

FIG. 3A illustrates the structure of a segment of the interlayer region 304, in accordance with an aspect of the present disclosure. FIG. 3B illustrates a sectional view, partially cut-away (A-A′) perspective of the segment of the interlayer region, highlighting the multilayer configuration of the interlayer region 304, in accordance with an aspect of the present disclosure. FIG. 3C illustrates a sectional view, partially cut-away (A-A′) perspective of the segment of the interlayer region, highlighting the material 328 located within the interlayer region 304, in accordance with an aspect of the present disclosure.

The wall of the cabinet comprises an outer sheet 320 (alternatively also be referred to as the first sheet 320) and an inner sheet 322 (alternatively also be referred to as the second sheet 322), with a space therebetween 304 (alternatively also be referred to as an interlayer region 304).

In an embodiment shown in FIG. 3B, interlayer region 304 is maintained as a vacuum cavity 326 serving as an acoustic barrier between the interior and exterior of the cabinet. The vacuum cavity 326, situated between the metal or composite panels, effectuates the noise reduction effect. By evacuating this space to a sub-atmospheric pressure, the medium necessary for efficient sound transmission, such as air or other gas is removed, thereby substantially impeding the propagation of airborne noise. Alternatively, as illustrated in an embodiment shown in FIG. 3C, the interlayer region 304 may be filled with a sound-absorbing material 328, such as acoustic foam, fiberglass, mineral wool, or a polymeric sound-damping composite. The interlayer region 304 situated between the metal or composite panels and filled with sound absorbing material 328 brings about the desired noise reduction effect.

The inner sheet 322 and the outer sheet 320 remain mechanically bonded (by fasteners, welding, or adhesive as suitable for the enclosure design and materials used) along their peripheries and at necessary intervals to maintain panel integrity under atmospheric loading, without introducing pathways or bridges that would compromise the vacuum or create new channels for vibration transmission.

Additionally, the panel can incorporate access ports or fittings to allow the application and maintenance of the vacuum condition. The wall construction depicted does not interfere with the mounting or maintenance of housed electronic components, and is compatible with standard cabinet installation practices.

The interlayer region 304 filled either with the sound absorbing material 328 or with the vacuum cavity 326 may be deployed on any portion of any of the front wall 108, the back wall 110, the left wall 112, the right wall 114, the roof 116 the base 118 or a door panel of the cabinet structure, according to noise insulation requirements. Alternatively, the interlayer region 304 filled either with the sound absorbing material 328 or with the vacuum cavity 326 may be deployed on the entire surface of any of the front wall 108, the back wall 110, the left wall 112, the right wall 114, the roof 116, the base 118, or a door panel of the cabinet structure, as per noise insulation requirements. Similarly, the interlayer region 304 filled either with the sound absorbing material 328 or with the vacuum cavity 326 may be deployed on the entire surface of each of the front wall 108, the back wall 110, the left wall 112, the right wall 114, the roof 116, the base 118 and a door panel of the cabinet structure, based on the noise insulation requirements. The disclosure allows for further variations, including the substitution of the vacuum cavity with a compressed layer of acoustic absorbent material, which serves a similar role in diminishing noise transmission through both absorption and decoupling.

Thus, the disclosure provides a multilayer panel for an equipment enclosure, wherein at least one wall incorporates a vacuum or compressed acoustic interlayer, realizing highly effective sound attenuation in a form manufacturable by conventional panel fabrication methods. This approach yields improved results compared to traditional single-wall, lined, or solid constructions, with broad applicability across indoor, outdoor, sealed, and open-site applications in high-performance electronics, communications, or industrial infrastructure.

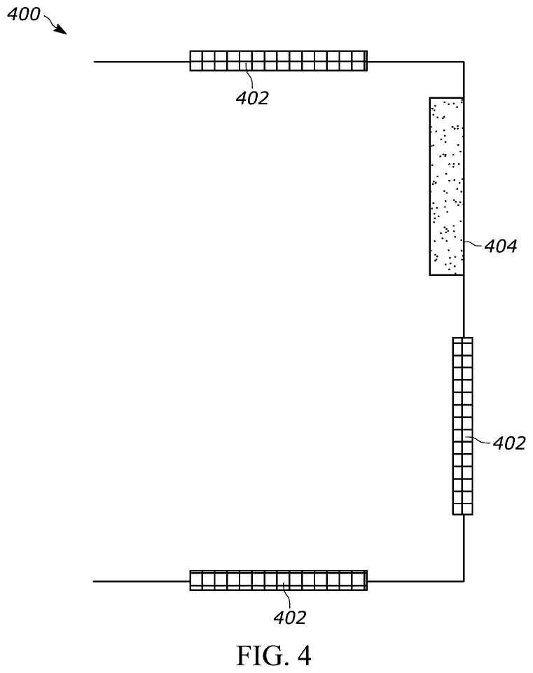

FIG. 4 illustrates a cross-sectional view of the proposed cabinet 400, in accordance with an embodiment of the present disclosure. The walls of the cabinet 400 are lined with specialized acoustic elements and airflow passages. The crosshatched rectangular assemblies 402 along the opposing walls represent labyrinthine baffles or acoustic dampers positioned to interfere with both direct and reflected sound wave paths. Baffles are optional enhancements separate from the interlayer panel, and that airflow impedance is managed (e.g., pressure drop targets), to preempt obviousness that “extra foam blocks airflow.” By increasing the length and complexity of the airflow and potential noise transmission pathways, these structures force sound to undergo multiple reflections and absorptions, drastically reducing the energy that escapes from inside the enclosure. On the vertical wall, the interlayer region 404 shows a composite or multilayered wall panel, specifically constructed with either a vacuum layer or a highly compressed sound-absorbing medium between its outer sheet and inner sheet. The representation emphasizes the integration of advanced sound attenuation panels in critical wall locations, further blocking airborne and structure-borne sound transmission through the cabinet 400.

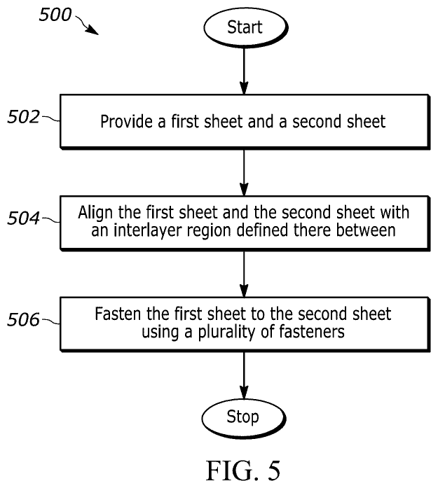

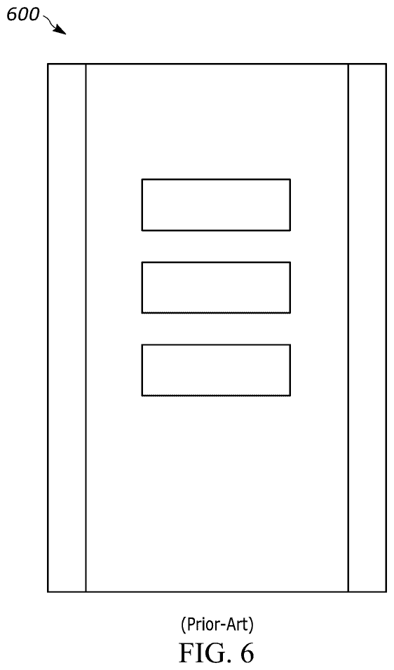

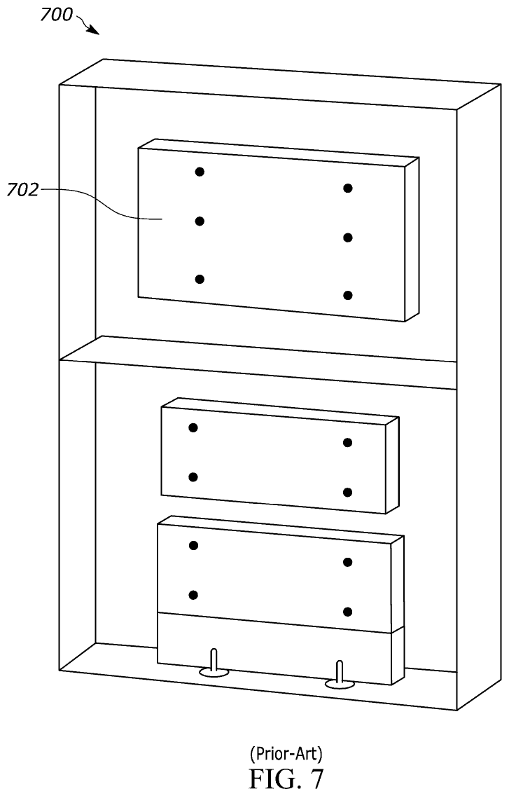

FIG. 5 illustrates a flowchart outlining a method 500 of constructing the proposed cabinet to facilitate noise reduction, in accordance with an aspect of the present disclosure. The process begins with the step of providing a first sheet and a second sheet, at step 502. Typically, both sheets are formed of metal or other rigid and durable material suitable for forming the structural walls of an equipment enclosure. Preferred sheet materials/thickness ranges from 0.8-1.5 mm steel or 1.2-2.0 mm aluminum. The first sheet and the second sheet are aligned with an interlayer region defined therebetween, at step 504. The alignment is performed to ensure uniform coverage, pressure, and the absence of air gaps or bridging structures which could diminish the acoustic performance of the cabinet. The process is finalized by securing the first sheet and the second sheet together using a plurality of fasteners, at step 506. The fasteners may be selected from bolts, rivets, welds, or adhesives. The fasteners may be arranged either to compress the interlayer material or to seal the cavity for vacuum retention, distributing pressure as necessary to remove air voids and optimize acoustic isolation. The result is a panel that can be integrated into any wall, floor, ceiling, or door of the finished cabinet structure.

This method supports reliable mass manufacture and enables consistent panel integrity, which is critical for maintaining both noise-reduction and vacuum over the operational life of the equipment enclosure. The interlayer vacuum, if employed, is established and maintained by evacuating air after assembly, requiring the positioning of appropriate vacuum fittings or ports. The completed cabinet thus employs panels produced in accordance with this sequence, yielding a product that is simple to build using standard industrial processes, while achieving an improvement in the attenuation of noise generated by powerful fans, transformers, switchgear, or other equipment typically contained within electronic or industrial cabinets. The stepwise workflow and layered panel arrangement shown in FIG. 5 embody the core inventive principle and provide the backbone for both the composition and assembly of the improved acoustic cabinet described in the present disclosure.

The disclosure offers several notable advantages that make it particularly suited for patent protection and commercial adoption in markets where noise control, equipment protection, and efficient cooling are critical. The principal advantage is its substantial improvement in noise reduction. By employing a vacuum cavity or a highly compressed sound-absorbing interlayer between cabinet panels, the need for sound transmission through air or other media is eliminated or significantly reduced, resulting in highly effective attenuation of both airborne and structural noise generated inside the cabinet. This enables use in settings with strict noise regulations or in environments where noise can cause operational disturbances or discomfort, such as offices, control rooms, residential installations, hospitals, and laboratories.

A further advantage is that the disclosure accomplishes this noise reduction without compromising the cabinet's thermal management performance. Unlike conventional cabinets that rely on acoustic foam lining or slowed-down fans (which may reduce effective cooling), the multilayer wall construction of this disclosure does not restrict airflow or cooling rates inside the enclosure. As a result, the housed electronic or electrical equipment can operate at optimal temperatures, thus enhancing component longevity, reducing failure rates, and supporting higher-density installations.

The inventive cabinet design lends itself to robust, durable construction. The wall assemblies can be fabricated from standard sheet materials (e.g., steel or aluminium) and conventional fastening methods, ensuring the finished structure retains mechanical strength, integrity, and resilience in demanding operating conditions, including outdoor and industrial environments. The approach avoids the disadvantages of internal foam products, which may degrade, absorb moisture, or contribute to fire load.

A further benefit is the ease and flexibility of integration. The noise-reducing panels and vacuum cavities can be incorporated into new cabinets at the manufacturing stage or retrofitted into existing designs, making this solution adaptable across a wide range of enclosure types, including passive and fan-cooled cabinets, sealed or outdoor-rated enclosures, and operator-access cabinets. The assembly process described allows for scalable production, tight quality control, and consistent acoustic performance.

In addition, since there is no reliance on delicate, exposed acoustic linings, the cabinet remains accessible for regular servicing, inspection, and hardware addition or removal. The design enables easy access to interior components without disturbing or damaging the noise attenuation features.

Finally, this disclosure offers a cost-effective and commercially competitive solution, as it uses readily available manufacturing materials, avoids specialty insulation products, and retains compatibility with standard fabricating and assembly practices. This enables manufacturers and end-users to realize the benefits of reduced equipment noise, preserved cooling, robust construction, and operational flexibility without incurring substantial added cost or design complexity. These practical and performance-related advantages mark the cabinet as a significant improvement over the prior art in the field of noise control for equipment enclosures.

It will be understood that the foregoing description of preferred embodiments is illustrative and not intended to be limiting. Various changes or modifications in form, detail, or arrangement of parts, as well as other embodiments, may be made without departing from the spirit and scope of the disclosure. The scope of protection sought is defined exclusively by the claims appended hereto.

While specific examples of interlayer media (such as vacuum cavities and compressed sound-absorbing materials) and particular manufacturing techniques have been described, it should be appreciated that equivalents, alternatives, or substitutions may be included for improved or alternative noise control, wall construction, assembly, or materials, as may be suited for particular applications or manufacturing requirements.

Reference in the specification to “one embodiment” or “an embodiment” means that a particular feature, structure, or characteristic described is included in at least one implementation of the disclosure. The appearances of such phrases in various places in the specification are not necessarily all referring to the same embodiment, nor are separate or alternative embodiments mutually exclusive of one another.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A cabinet for housing electronic components, the cabinet comprising:
a plurality of walls defining an enclosure, wherein at least one wall of the plurality of walls comprises:
a first sheet;
a second sheet the second sheet being substantially coextensive with and spaced-apart from the first sheet; and
an interlayer region disposed between the first sheet and the second sheet, the interlayer region comprising an interlayer medium for inhibiting transmission of sound from an interior of the enclosure to an exterior, wherein the interlayer medium comprises one of a vacuum cavity or a compressed sound-absorbing material.

2. The cabinet of claim 1, wherein the interlayer medium comprises the compressed sound-absorbing material, further comprising a plurality of fasteners coupling the first sheet and the second sheet, wherein the plurality of fasteners are configured to maintain compression of the compressed sound-absorbing material to eliminate air gaps therein.

3. The cabinet of claim 2, wherein the plurality of fasteners comprises at least one of a bolt, a rivets, a welding bond, or an adhesive bond.

4. The cabinet of claim 2, wherein the plurality of fasteners are configured to compress the compressed sound-absorbing material to at least 80% of its uncompressed thickness.

5. The cabinet of claim 1, wherein the compressed sound-absorbing material is selected from the group comprising of an acoustic foam, a fiberglass, a mineral wool, and a polymeric sound-damping composite.

6. The cabinet of claim 1, further comprising a vacuum pump for maintaining the vacuum cavity in the interlayer region.

7. The cabinet of claim 6, wherein the vacuum cavity has a pressure less than 100 Pa.

8. The cabinet of claim 1, wherein the first sheet and the second sheet are made of metal.

9. The cabinet of claim 1, wherein the cabinet is one of an active cabinet or a passive cabinet.

10. The cabinet of claim 1, wherein the at least one wall having the interlayer medium is a side wall, a top wall, or a door of the cabinet.

11. The cabinet of claim 1, wherein the cabinet is an Outdoor Site Premises (OSP) enclosure.

12. The cabinet of claim 1, wherein the vacuum cavity forms a vacuum shroud to minimize the propagation of sound waves.

13. A method of manufacturing a wall panel associated with a cabinet for housing electronic components, the method comprising:
providing a first sheet and a second sheet;
aligning the first sheet and the second sheet with an interlayer region disposed therebetween; and
securing the first sheet to the second sheet using a plurality of fasteners to one of:
seal the interlayer region to define a vacuum cavity, or
compress a sound-absorbing material positioned between the first sheet and the second sheet to eliminate air gaps,
to inhibit sound transmission from an interior of the cabinet to an exterior of the cabinet.

14. The method of claim 13, further comprising evacuating air from the interlayer region to create a vacuum cavity within the interlayer region.

15. The method of claim 14, wherein the vacuum cavity is created using a vacuum pump.

16. The method of claim 13, wherein the sound-absorbing material is compressed by applying a torque of at least 5 Nm to each fastener of the plurality of fasteners.

17. The method of claim 13, wherein the plurality of fasteners comprise at least one of a bolt, a rivets, a welding bond, or an adhesive bond.

18. The method of claim 13, wherein the sound-absorbing material is selected from the group consisting of an acoustic foam, a fiberglass, a mineral wool, and a polymeric sound-damping composite.

19. The method of claim 13, wherein the vacuum cavity forms a vacuum shroud to minimize propagation of sound waves.

20. The method of claim 13, wherein the first sheet and the second sheet are made of metal.
